(19) United States
(12) Patent Application Publication
(10) Pub. No.: US 2009/0020791 A1
(43) Pub. Date: Jan. 22, 2009

(54) PROCESS METHOD TO FABRICATE CMOS CIRCUITS WITH DUAL STRESS CONTACT ETCH-STOP LINER LAYERS

(76) Inventors: Shaofeng Yu, Plano, TX (US); Juanita DeLoach, Plano, TX (US); Brian A. Smith, Rolla, MO (US); Yaw S. Obeng, Frisco, TX (US); Scott Gregory Bushman, Richardson, TX (US)

Correspondence Address: TEXAS INSTRUMENTS INCORPORATED, P O BOX 655474, M/S 3999, DALLAS, TX, 75265, US

(21) Appl. No.: 11/778,321

(22) Filed: Jul. 16, 2007

(51) Int. Cl. H01L 21/8238

(52) U.S. Cl. 257/288; 438/199; 257/E21.632

(57) ABSTRACT

Exemplary embodiments provide IC CMOS devices having dual stress layers and methods for their manufacture using a buffer layer stack between the two types of the stress layers. The buffer layer stack can include multiple buffer layers formed between a first type stress layer (e.g., a tensile stress layer) and a second type stress layer (e.g., a compressive stress layer) during the CMOS fabrication. Specifically, the buffer layer stack can be formed after the etching process of the first type stress layer but prior to the etching process of the second type stress layer, and thus to protect the etched first type stress layer during the subsequent etching process of the overlaid second type stress layer. In addition, a portion of the buffer layer stack can be formed between, for example, the compressive stress layer and the underlying PMOS device to enhance their adhesion.

### DESCRIPTION OF THE INVENTION

1. Field of the Invention

This invention relates generally to complementary metal oxide semiconductor (CMOS) devices and methods for their manufacture and, more particularly, to dual stress layers of CMOS devices.

2. Background of the Invention

Dual stress layers (DSL) have been proven to be an effective way to improve both NMOS and PMOS transistor performance of CMOS devices. This is because the carrier mobility of each channel region of the NMOS and PMOS transistors can be increased by the stress exerted in the channel region from its corresponding stress layer.

Generally, two types of stress layers, including tensile stress layers and compressive stress layers, can be formed over CMOS transistor structures. In a CMOS fabrication process, each stress layer can be deposited, patterned and etched. Often there is a buffer layer formed between the two types stress layers during the fabrication. For example, a second stress layer (e.g., a compressive stress layer for a PMOS) can be formed over a buffer layer, which is formed over a first stress layer (e.g., a tensile stress layer for an NMOS).

However, this conventional fabrication process has drawbacks and disadvantages. For example, one drawback is that the etching process of the second stress layer often thins the underlying first stress layer due to the similarity in material properties. Another drawback in the conventional fabrication process is that the adhesion of the stress layers on the surface of CMOS structures is sometimes not adequate, which can result in strain loss in the CMOS channel regions and/or partial or full delamination of the layers.

Thus, there is a need to overcome these and other problems of the prior art and to provide a technique to fabricate CMOS circuits with dual stress layers to provide effective stress exertion in the channel region.

### SUMMARY OF THE INVENTION

According to various embodiments, the present teachings include a method for forming a CMOS device. The CMOS device can be formed by forming a first buffer layer over a first type stress layer that is formed over a first polarity type device. A second buffer layer can then be formed over the first buffer layer and over a second polarity type device. Over a portion of the second buffer layer that is formed over the second polarity type device, a second type stress layer can then be formed.

According to various embodiments, the present teachings also include a CMOS device. The CMOS device can include a first oxide layer disposed over a tensile stress layer that is disposed over an NMOS device. The CMOS device can also include a second oxide layer disposed over the first oxide layer and over a PMOS device. The CMOS device can further include a compressive stress layer disposed over a portion of the second oxide layer that is disposed over the PMOS device.

According to various embodiments, the present teachings further include a method for forming a CMOS device. In this method, a first oxide layer can be formed over a tensile stress nitride layer that is formed over an NMOS device and a PMOS device. The PMOS device can then be exposed by removing portions of the first oxide layer and the tensile stress nitride layer over the PMOS device. Over the remaining portion of the first oxide layer and over the exposed PMOS device, a second oxide layer can be formed, followed by forming a compressive stress nitride layer thereover. A portion of the compressive stress nitride layer that is formed over the NMOS device can then be removed.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1A is a cross sectional view of an exemplary CMOS structure suitable for use in accordance with the present teachings.

FIGS. 1B-1F depict an exemplary process flow for a first exemplary CMOS device having dual stress layers in accordance with the present teachings.

FIG. 2 depicts a second exemplary CMOS device having dual stress layers in accordance with the present teachings.

FIG. 3 depicts a third exemplary CMOS device having dual stress layers in accordance with the present teachings.

FIG. 4 depicts a forth exemplary CMOS device having dual stress layers in accordance with the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Exemplary embodiments provide integrated circuit (IC) CMOS devices having dual stress layers and methods for their manufacture using a buffer layer stack between the two types of the stress layers. The buffer layer stack can include multiple buffer layers formed between a first type stress layer (e.g., a tensile stress layer) and a second type stress layer (e.g., a compressive stress layer) during the CMOS fabrication. Specifically, the buffer layer stack can be formed after the etching process of the first type stress layer but prior to the etching process of the second type stress layer, to protect the etched first type stress layer during the subsequent etching process of the overlaid second type stress layer. By using the buffer layer stack post etching of the first type stress layer, the thickness of the buffer region between the two types stress layers during the fabrication can be independently controlled. In addition, a portion of the buffer layer stack can be formed between, for example, the compressive stress layer and the underlying PMOS device to enhance their adhesion. In various embodiments, in addition to the buffer layer stack, the disclosed devices and methods can include more buffer layers formed adjacent to the first and/or second type stress layers.

As disclosed herein, the buffer layers and the stress layers can be formed using suitable dielectric materials, such as, for example, silicon nitride, silicon oxide, silicon oxynitride, silicon carbide, or silicon oxycarbide (SiOC). For example, the disclosed buffer layers, such as each layer of the buffer layer stack, can include a silicon oxide layer. The oxide buffer layer can be deposited, patterned and etched using any suitable methods known to one of ordinary skill in the art. For example, the oxide buffer layer can be deposited by various CVD (i.e., chemical vapor deposition) techniques, such as PECVD (plasma enhanced chemical vapor deposition), or HDPCVD (high-density plasma chemical vapor deposition); and the oxide buffer layer can be etched by, for example, a wet etch process such as a buffered oxide etch (BOE), or a dry etch process such as a plasma etch (e.g. RIE, reactive ion etching).

The disclosed stress layers can be high stress layers, e.g., tensile high stress layers or compressive high stress layers, used to strain the underlying CMOS transistors. The stress layers can include a silicon nitride layer, which can be formed, patterned and etched during the CMOS fabrication processes. For example, the nitride stress layer can be formed using various CVD techniques, such as HDPCVD (high-density plasma chemical vapor deposition), and PECVD (plasma enhanced chemical vapor deposition) process using precursors such as silane (SiH₄) and nitrous oxide (N₂O). In various embodiments, Bis(TertiaryButylAmino)Silane (BTBAS) can be used as precursor for the deposition of the nitride stress layer. The nitride stress layer can be etched by, for example, a dry etch process such as a plasma etch (e.g., RIE).

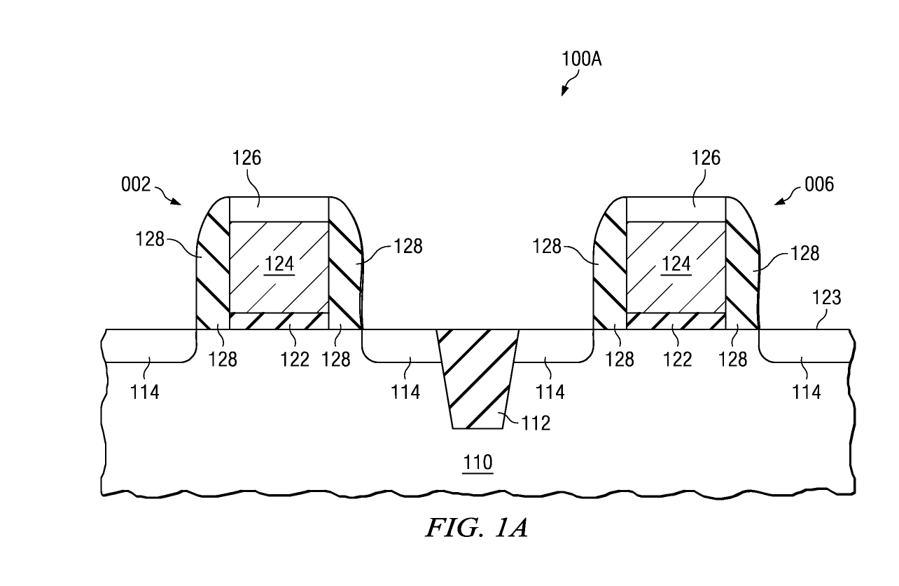

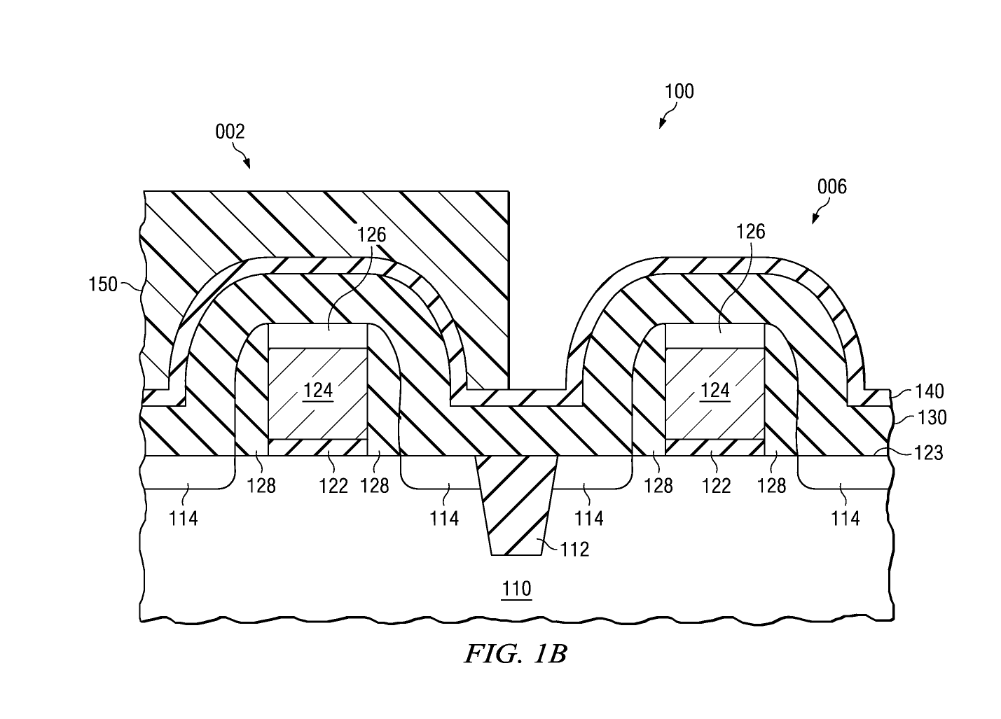

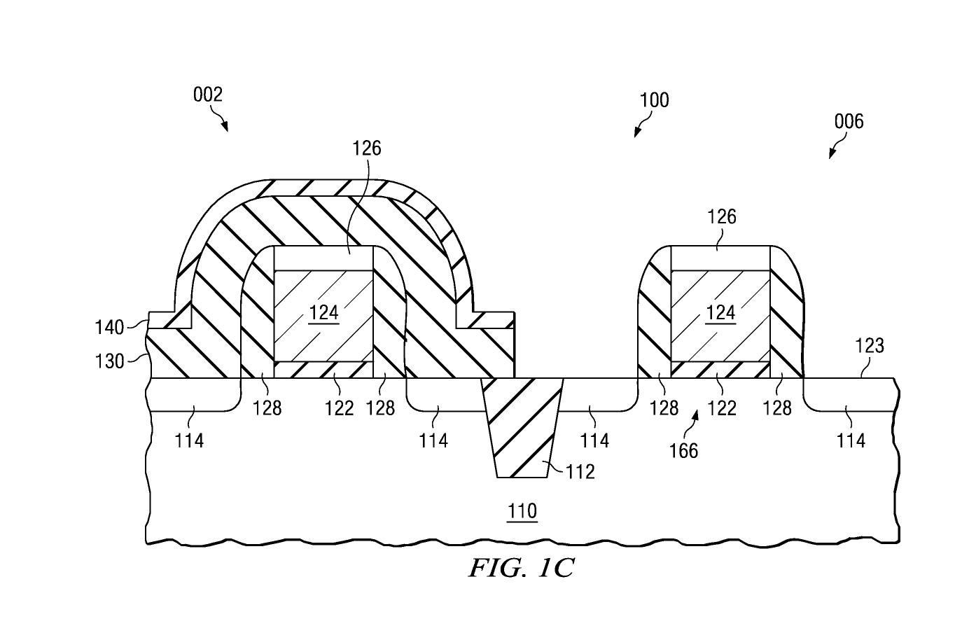

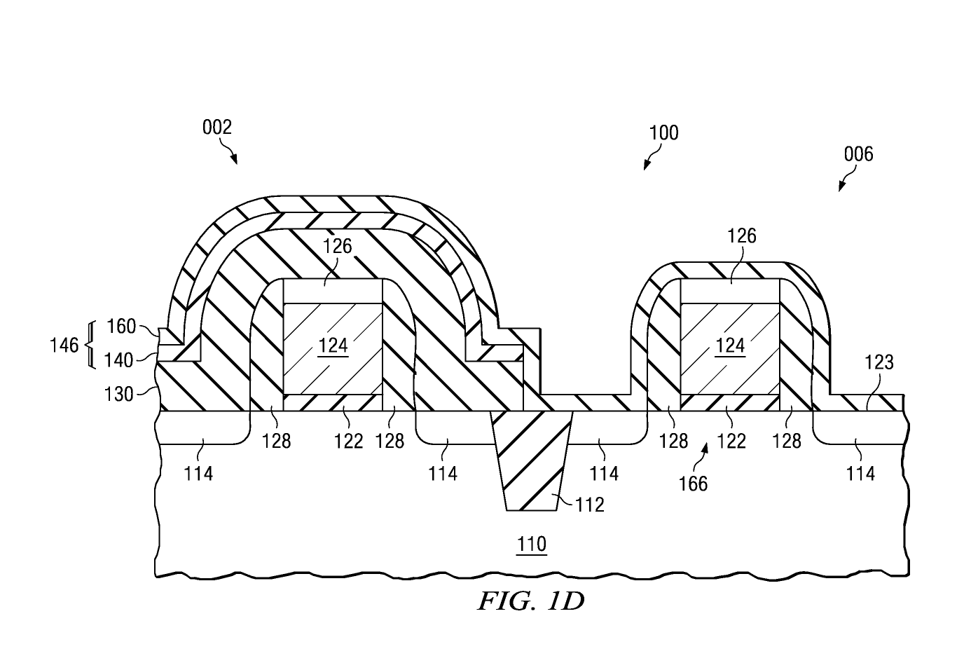

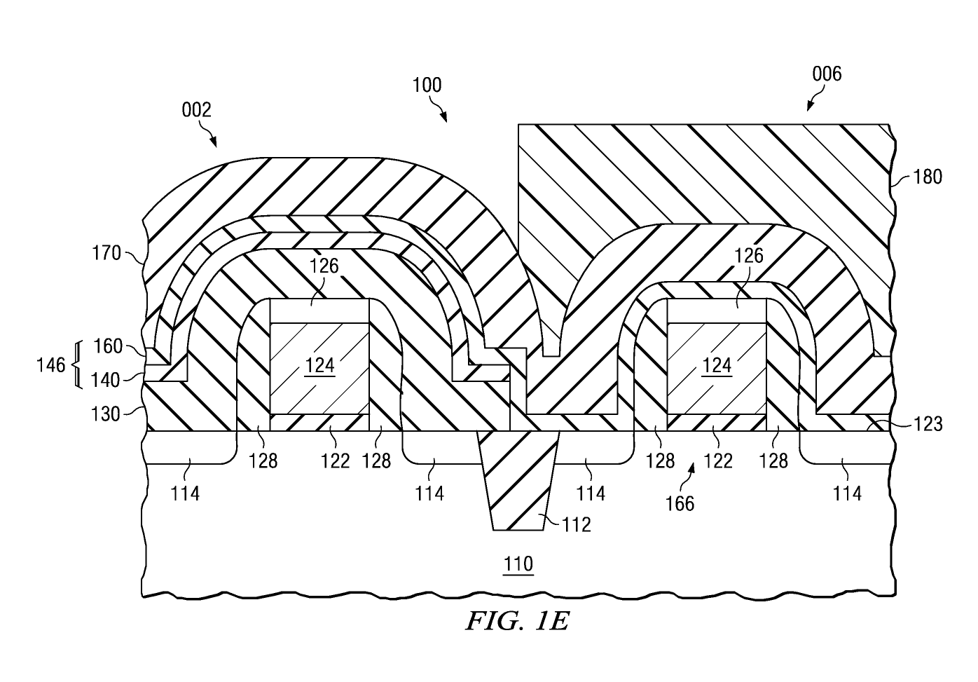

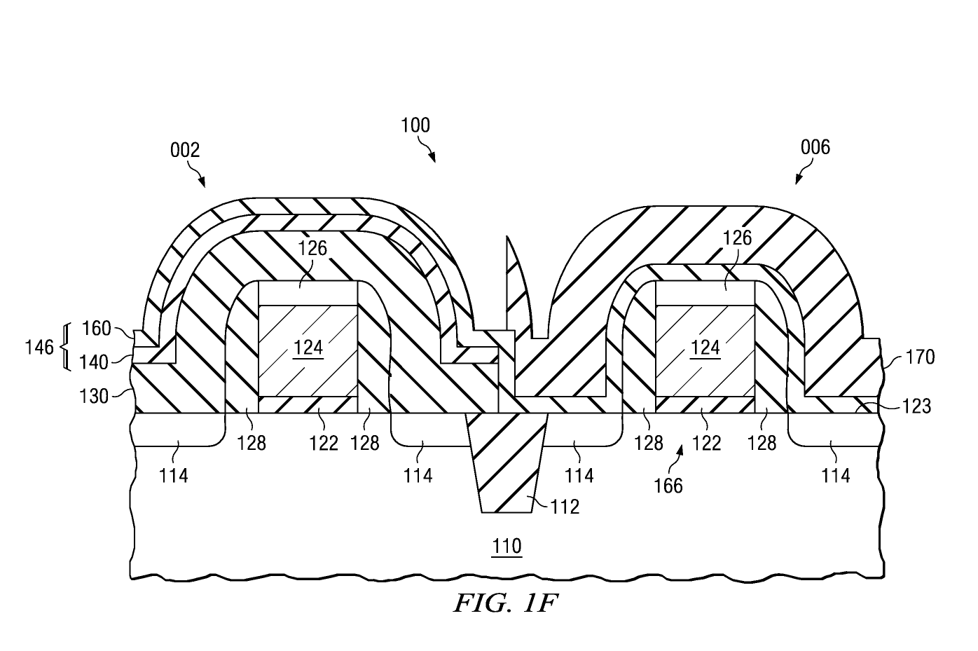

FIG. 1A is a cross sectional view of an exemplary CMOS structure 100A suitable for use in accordance with the present teachings. It should be readily apparent to one of ordinary skill in the art that the CMOS structure 100A depicted in FIG. 1A represents a generalized schematic illustration and that other layers/structures/regions can be added or existing layers/structures/regions can be removed or modified.

Specifically, the CMOS structure 100A can include a device at a particular process stage of known IC manufacturing. For example, the CMOS structure 100A can include a semiconductor substrate 110, and a pair of exemplary complementary metal oxide semiconductor (CMOS) devices, i.e., an NMOS device 002 and a PMOS device 006, which can be formed on the semiconductor substrate 110. The NMOS device 002 and the PMOS device 006 can be electrically isolated from one another by an isolation structure 112.

The isolation structure 112 can be formed in the semiconductor substrate 110 using suitable dielectric materials, for example, silicon oxide. The isolation structure 112 can include, for example, shallow trench isolation (STI) structures, local oxidation structures (LOCOS), or a combination thereof and/or other suitable isolation structures.

Each of the NMOS device 002 and the PMOS device 006 can include a transistor gate stack formed on the surface of the semiconductor 110. The transistor gate stack can include a gate electrode 124 formed on a gate dielectric layer 122. The gate electrode 124 can include a conductive material, such as, for example, doped polycrystalline silicon, various metals and/or metal silicides. The gate dielectric layer 122 can include any suitable dielectric material, for example, silicon oxide, silicon nitride, silicon oxynitride, high k dielectric materials such as hafnium oxide, hafnium silicon oxynitride, and other suitable materials.

Sidewall structures 128 for each of the NMOS device 002 and the PMOS device 006 can be formed adjacent to the gate stack and on the semiconductor substrate 110 using standard processing technologies. The sidewall structures 128 can include dielectric material, for example, silicon oxide, silicon nitride, BTBAS, or any other suitable dielectric materials.

Following the formation of the sidewall structures 128, transistor source and drain diffusion regions 114 can be formed by implanting suitable dopants into the semiconductor substrate 110. Following the formation of the source and drain regions 114, the metal silicidation of the gate electrode 124 (e.g., polysilicon) and the doped source and drain diffusion regions 114 can taken place. Metal silicide layer 126 can therefore be formed on the gate electrode 124, and the source and drain diffusion regions 114 can therefore include metal silicide layers. In an exemplary embodiment, the metal silicide can include, for example, nickel silicide, nickel platinum silicide, cobalt silicide, or any other suitable metal silicide materials. In the case where the gate electrode 124 includes a metal or a metal silicide, no metal silicide layer 126 can be formed on this gate electrode.

The CMOS structure 100A can further include a surface 123 including each surface of the entire structures, i.e., the NMOS device 002, the PMOS device 006, and the isolation structure 112. Each of the NMOS device 002 and the PMOS device 006 can include the metal silicide layer 126 formed over the gate stack, the sidewall structures 128 and the silicided source and drain diffusion regions 114.

FIGS. 1B-1F depict an exemplary CMOS device 100 having dual stress layers over the silicided NMOS 002 and the silicided PMOS 006 devices in accordance with the present teachings. It should be readily apparent to one of ordinary skill in the art that the semiconductor device 100 depicted in FIGS. 1B-1F represents a generalized schematic illustration and that other layers/structures/regions can be added or existing layers/structures/regions can be removed or modified,

In FIG. 1B, the device 100 can include a first buffer layer 140 formed over a tensile stress layer 130 over the surface 123, i.e., the entire surface of the CMOS structure 100A shown in FIG. 1A. The tensile stress layer 130 can be a tensile high stress nitride (i.e., T-HSN) layer having a tensile stress of, for example, about 1.3 GPa to about 2.3 GPa. In an exemplary embodiment, the tensile stress layer 130 can have a tensile stress of about 1.6 GPa. In various embodiments, the tensile stress layer 130 can operate as a PMD liner to protect the underlying transistor, e.g., the NMOS device 002, from a subsequently formed pre-metal dielectric (PMD) material. For example, the PMD liner can protect the underlying transistor from metal contamination in the subsequent back end of line process. In addition, the tensile stress layer 130 can be used as an etch-stop layer in forming openings for contacts to transistor terminals, through the PMD material. In various embodiments, the thickness of the tensile stress layer 130 can be related to the density of the transistors on the integrated circuit and in particular to the distance between two closest neighboring transistors. For example, the tensile stress layer 130 can have a thickness of about 200 angstroms to about 1200 angstroms. In an exemplary embodiment, the thickness can be about 500 angstroms.

The first buffer layer 140 can be a silicon oxide layer deposited on the tensile stress layer 130 in, for example, the PMD deposition tool. The first buffer layer 140 can have a thickness of, for example, about 50 to about 500 angstroms, In an exemplary embodiment, the thickness can be about 100 angstroms. The first buffer layer 140 can be formed to protect the tensile stress layer 130 from, e.g., a chemical poisoning with an overlaid photoresist during the subsequent patterning and etching processes of the tensile stress layer 130. In addition, the first buffer layer 140 can be used as an etch stop layer during a subsequent etching process of the compressive stress layer.

Still in FIG. 1B, the device 100 can further include a patterned photoresist 150, which can be formed to cover the NMOS device 002 region and to expose the PMOS device 006 region for subsequent patterning and etching processes.

In FIG. 1C, removal of the exposed portions of the first buffer layer 140 as well as the tensile stress layer 130 can be performed. These removal can be implemented, for example, through a reactive ion etch (RIE) of both the exemplary oxide and nitride materials and the etch process can be stopped on a portion of the surface 123 as shown in FIG. 1C. Notably, the sidewall spacers 128 associated with the PMOS device 006 can be somewhat reduced in size as a result of the removal of the portion of the tensile stress layer 130. Following the removal of PMOS (i.e., the device 006) associated tensile stress layer 130, the patterned photoresist 150 can also be removed.

In FIG. 1D, a second buffer layer 160 can be formed on the entire surface of the device 100 shown in FIG. 1C, i.e., on each surface of the NMOS associated portion of the first buffer layer 140 and the exposed portion of the surface 123 (see FIG. 1C). The second buffer layer 160 can be a silicon oxide layer as similar to the first buffer layer 140. The second buffer layer 160 can be thin and have a thickness of, for example, about 30 angstroms to about 200 angstroms. In an exemplary embodiment, the thickness can be about 50 angstroms or less.

In FIG. 1E, a compressive stress layer 170 can be formed on the second buffer layer 160, i.e., the entire surface of the device 100 shown in FIG. 1D. The compressive stress layer 170 can be a compressive high stress nitride (C-HSN) layer having a compressive stress of, for example, about 2.0 GPa to about 3.5 GPa. In an exemplary embodiment, the compressive stress can be about 2.8 GPa. In various embodiments, the compressive stress layer 170 can be formed by high density plasma (HDP) deposition or plasma enhanced CVD (PECVD). The compressive stress layer 170 can operate as a PMD liner to protect the underlying transistor, e.g., the PMOS device 006, from a subsequently formed pre-metal dielectric (PMD) material. The compressive stress layer 170 can also be used as an etch-stop layer in forming openings for contacts to transistor terminals, through the PMD material. In various embodiments, the thickness of the compressive stress layer 170 can also be related to the density of the transistors on the integrated circuit and in particular to the distance between two closest neighboring transistors. For example, the compressive stress layer 170 can have a thickness of about 200 to about 1200 angstroms. In an exemplary embodiment, the thickness can be about 500 angstroms.

Following the formation of the compressive stress layer 170, a second patterned photoresist 180 can be formed to cover the PMOS associated portion of the compressive stress layer 170 leaving the NMOS associated portion of the compressive stress layer 170 exposed.

In FIG. 1F, removal of the exposed portion of the compressive stress layer 170 over the NMOS device 002 can be performed. This removal can be implemented, for example, through a plasma etch, with the etch process stopped on the second buffer layer 160. After the removal of the NMOS associated portion of the compressive stress layer 170, the patterned photoresist 180 can also be removed.

In this manner as shown in FIGS. 1D-1F, the second buffer layer 160 of the CMOS device 100 can include an NMOS associated portion and a PMOS associated portion. Specifically, the NMOS associated portion of the second buffer layer 160 can be formed on the first buffer layer 140, forming a buffer layer stack 146 over the NMOS device 002. That is, the second buffer layer 160, having an exemplary thickness of about 50 angstroms or less, can add additional buffer thickness to the first buffer layer 140. During the fabrication processes, the buffer layer stack 146 (see FIGS. 1D-1E) can be formed after the removal of the PMOS associated portion of the tensile stress layer 130 but before the subsequent deposition/etching processes of the compressive stress layer 170 The formation of the buffer layer stack 146 can therefore protect the tensile stress layer 130 during the removal of the overlaid portion of the compressive stress layer 170 (see FIG. 1F) due to the added buffer thickness from the second buffer layer 160.

In addition, the PMOS associated portion of the second buffer layer 160 can be formed between the compressive stress layer 170 and the PMOS device 006 to improve their adhesion. This improved adhesion through the second buffer layer 160 can facilitate a more effective compressive stress exertion in the channel region 166 of the PMOS device 006 from the compressive stress layer 170.

Furthermore, in various embodiments, a thicker first buffer layer 140 can not replace the buffer layer stack 146 (see FIGS. 1D-1F) that includes, for example, the second buffer layer 160 overlaid on the first buffer layer 140. This is because during the removal process of the PMOS associated portion of the tensile stress layer 130 (see FIGS. 1B-1C), the first buffer layer 140 can first be removed followed by the removal of the tensile stress layer 130, and exposing the PMOS device 006. A thicker first buffer layer can have excessive oxide removal process. In addition, this removal (see FIG. 1C) of the PMOS associated portions of the first buffer layer 140 and the tensile stress layer 130 can result in no buffer layer being formed between the subsequently compressive stress layer 170 and the PMOS associated portion of the surface 123 in a final device (not shown). That is, the compressive stress layer 170 can be formed directly on the PMOS device 006 with a poor adhesion generated there between, which can cause less effective compressive stress transfer in the PMOS channel region 166 as well as delamination of related layers. Therefore, the formation of the second buffer layer 160 can improve the adhesion between the compressive stress layer 170 and the underlying PMOS device 006 (see FIG. 1F) to effectively exert compressive strain in the PMOS channel region 166.

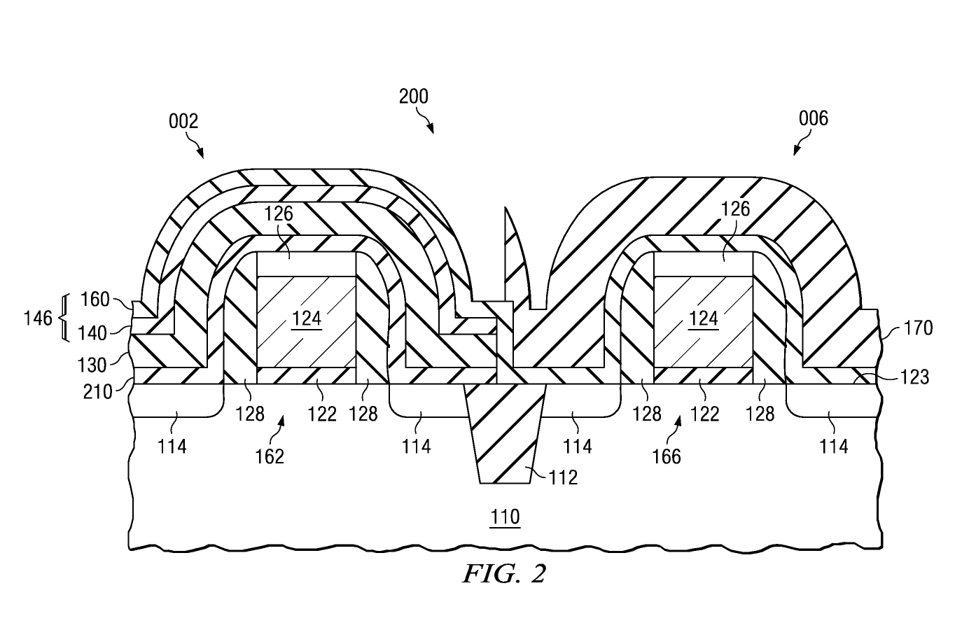

In various embodiments, the disclosed CMOS devices can include more buffer layers besided the buffer layer stack 146. For example, a third buffer layer and/or a forth buffer layer can be formed adjacent to the tensile stress layer 130 and/or the compressive stress layer 170. More exemplary CMOS devices are shown in FIGS. 2-4.

FIG. 2 depicts a second exemplary CMOS device 200 having a third oxide layer in accordance with the present teachings. Specifically, as shown, the third oxide layer 210 can be formed between the tensile stress layer 130 and the NMOS device 002, i.e., on the NMOS associated portion of the surface 123.

The fabrication process (not shown) for forming the device 200 can be similar to that described in FIG. 1A through FIG. 1F. For example, starting from the CMOS structure 100A in FIG. 1A, the third oxide layer 210 (not shown) can be formed on the entire surface of the CMOS structure 100A, that is, on the surface 123. The tensile stress layer 130 can then be formed thereon and followed by the formation of the first oxide layer 140. As similarly described in the process flow for device 100 in FIG. 1C through FIG. 1F, the PMOS associated portions of the third oxide layer 210, the tensile stress layer 130, and the first oxide layer 140 can then be removed from the PMOS associated portion of the surface 123 (similarly to FIG. 1C); the second oxide layer 160 can then be formed on the entire device forming a buffer layer stack 146 on the NMOS associated portion of the tensile stress layer 130 and having a portion of the second oxide layer 160 over the PMOS device 006 region (similarly to FIG. 1D); the compressive stress layer 170 can then be formed on the entire surface of the second buffer layer 160 (similarly to FIG. 1E); and the NMOS associated portion of the compressive stress layer 170 can be removed to form the device 200 shown in FIG. 2.

In this manner, the third buffer layer 210 can be formed to protect the PMOS device 006, for example, during the etching process of the tensile stress layer 130. In addition, the third buffer layer 210 can be used to enhance the adhesion between the tensile stress layer 130 and the NMOS device 002. The thickness of the buffer layer 210 can vary as desired. However, a very thick third buffer layer 210 can reduce the stress transfer effectiveness to the channel region 162 of the NMOS device 002. In an exemplary embodiment, the thickness of the third buffer layer 210 can be about 30 angstroms to about 100 angstroms, such as about 50 angstroms.

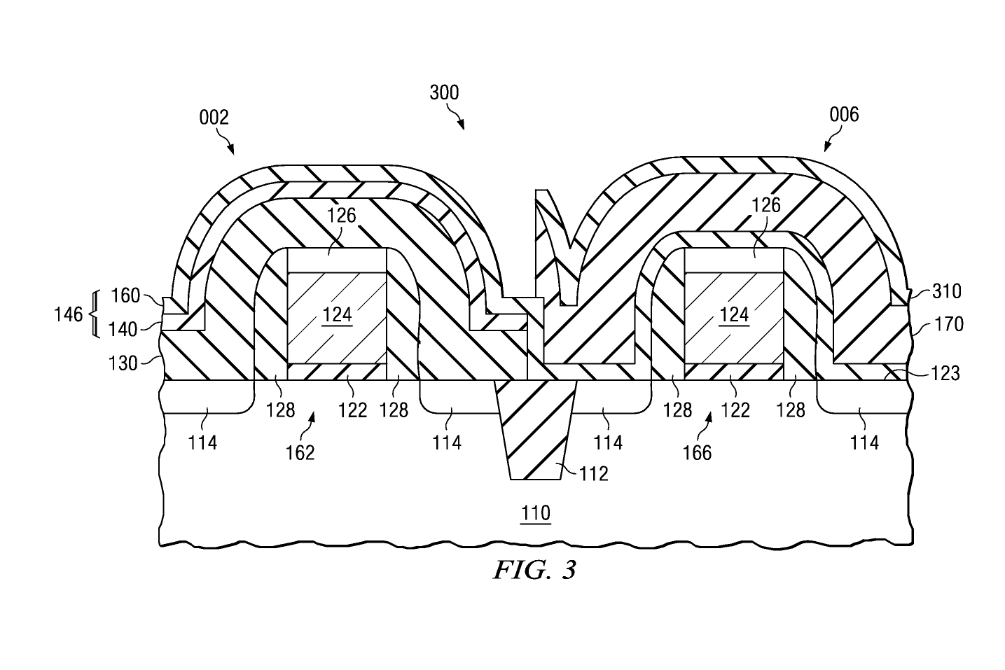

In various embodiments, a forth oxide layer can be involved in the CMOS device 100 shown in FIGS. 1A-1F and/or the device 200 shown in FIG. 2. For example, FIG. 3 depicts a third exemplary CMOS device 300 in accordance with the present teachings.

In FIG. 3, the forth oxide layer 310 can be added to the exemplary device 100. Specifically, as shown, the forth oxide layer 310 can be formed on the PMOS associated surface of the compressive stress layer 170 of the device 100 in FIG. 1F. The process flow for forming the device 300 can be similar to that described from FIG. 1A through FIG. 1F. For example, following the process flow for device 100 in FIG. 1E where the compressive stress layer 170 has been formed on the entire surface of the exemplary CMOS device (i.e., on the second buffer layer 160), the forth oxide layer 310 (not shown in FIG. 1E) can be formed on the compressive stress layer 170. The NMOS associated portions of the compressive stress layer 170 and the overlaid forth oxide layer 310 (not shown) can then be removed and resulting in the device 300 shown in FIG. 3, In this manner, the forth oxide layer 310 can be formed to protect the compressive stress layer 170 from, for example, a chemical reaction with the overlaid photoresist during the patterning and etching processes of the compressive stress layer 170.

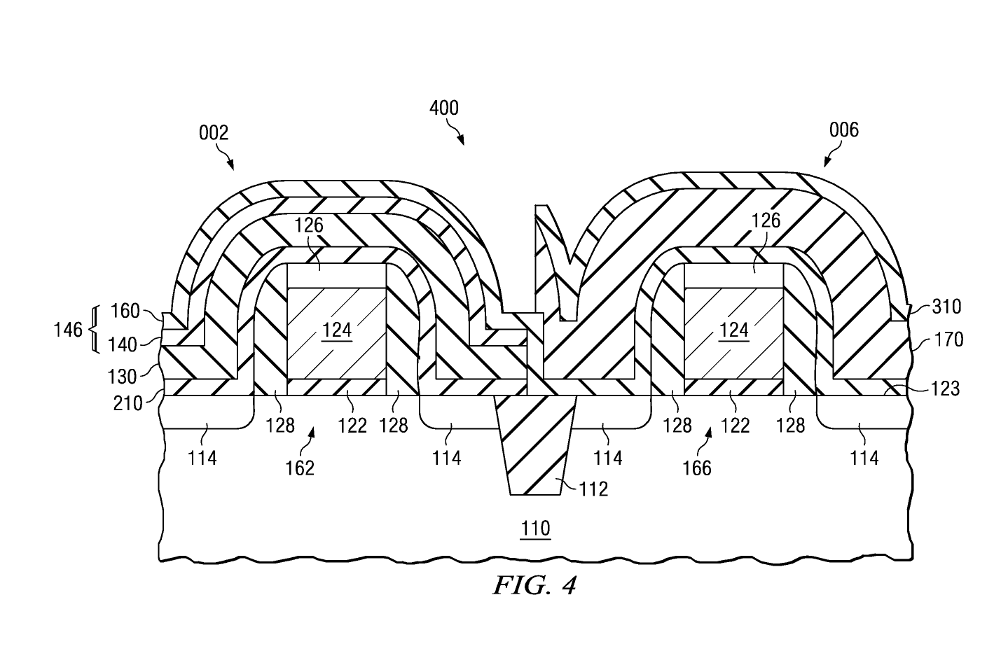

In various embodiments, two more buffer layers, e.g., the third buffer layer seen in FIG. 2 and the forth buffer layer seen in FIG. 3, can be added to the CMOS device 100 shown in FIGS. 1A-1F. FIG. 4 depicts a forth exemplary CMOS device 400 in accordance with the present teachings.

As shown in FIG. 4, the device 400 can include the third oxide layer 210 formed between the tensile stress layer 130 and the NMOS device 002 to facilitate their adhesion and to enhance the tensile stress exertion in the NMOS channel region 162. The device 400 can also include the forth oxide layer 310 formed on top of the compressive stress layer 170 to protect this layer from the photoresist poisoning during the fabrication processes. In various embodiments, the device 400 can be formed by combining the fabrication processes that are described in FIGS. 1A-1F, FIG. 2, and FIG. 3.

In various embodiments, conventional device processing operation can be continued to complete the CMOS process for devices shown in FIG. 1F, FIG. 2, FIG. 3 and FIG. 4. In various embodiments, the PMOS associated processes can be performed prior to the NMOS associated processes, and vice versa. For example, the compressive stress layer 170 can be processed prior to the fabrication of the tensile stress layer 130, and the NMOS associated portion of the compressive stress layer 170 can be first removed following the deposition of the tensile stress layer 130 with the PMOS associated portion subsequently removed.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a CMOS device comprising:
forming a first buffer layer over a first type stress layer, wherein the first type stress layer is formed over a first polarity type device;
forming a second buffer layer over the first buffer layer and over a second polarity type device; and
forming a second type stress layer over a portion of the second buffer layer that is formed over the second polarity type device.

2. The method of claim 1, further comprising forming one or two of a third buffer layer and a forth buffer layer, wherein
the third buffer layer is formed between the first type stress layer and the first polarity type device, and
the forth buffer layer is formed over the second type stress layer.

3. The method of claim 2, wherein the third buffer layer is formed having a thickness of about 30 angstroms to about 100 angstroms.

4. The method of claim 1, wherein forming the first buffer layer over the first type stress layer over the first polarity type device comprises,
forming a buffer layer over a first type stress layer that is formed over the first polarity type device and over the second polarity type device, and
removing portions of the buffer layer and the first type stress layer that are formed over the second polarity type device.

5. The method of claim 1, wherein forming the second type stress layer over the second polarity type device comprises,
forming a second type stress layer over the second buffer layer, wherein the second buffer layer is formed over each of the first and the second polarity type devices, and
removing a portion of the second type stress layer that is formed over the first polarity type device.

6. The method of claim 1, wherein each of the first type stress layer and the second type stress layer comprises a silicon nitride layer.

7. The method of claim 1, wherein the first type stress layer is one of a tensile stress layer and a compressive stress layer, and the second type stress layer is the other of the tensile stress layer and the compressive stress layer.

8. The method of claim 7, wherein the tensile stress layer is formed having a tensile stress ranging from about 1.3 GPa to about 2.3 GPa.

9. The method of claim 7, wherein the compressive stress layer is formed having a compressive stress ranging from about 2.0 GPa to about 3.5 GPa.

10. The method of claim 1, wherein each of the first buffer layer and the second buffer layer is a silicon oxide layer.

11. The method of claim 1, wherein the first buffer layer has a thickness ranging from about 50 angstroms to about 500 angstroms.

12. The method of claim 1, wherein the second buffer layer has a thickness ranging from about 30 angstroms to about 200 angstroms.

13. A CMOS device comprising:
a first oxide layer disposed over a tensile stress layer disposed over an NMOS device;
a second oxide layer disposed over the first oxide layer and over a PMOS device; and
a compressive stress layer disposed over a portion of the second oxide layer that is disposed over the PMOS device.

14. The device of claim 13, further comprising one or two of a third oxide layer and a forth oxide layer, wherein
the third oxide layer is disposed between the tensile stress layer and the NMOS device, and
the forth oxide layer is disposed on the compressive stress layer.

15. The device of claim 14, wherein the third oxide layer has a thickness ranging from about 30 angstroms to about 100 angstroms.

16. The device of claim 13, wherein each of the tensile stress layer and the compressive stress layer comprises a silicon nitride layer.

17. The device of claim 13, wherein the tensile stress layer has a tensile stress ranging from about 1.3 GPa to about 2.3 GPa and a thickness ranging from about 200 angstroms to about 1200 angstroms.

18. The device of claim 13, wherein the compressive stress layer has a compressive stress ranging from about 2.0 GPa to about 3.5 GPa and a thickness ranging from about 200 angstroms to about 1200 angstroms.

19. The device of claim 13, wherein the first oxide layer has a thickness ranging from about 50 angstroms to about 500 angstroms.

20. The device of claim 13, wherein the second oxide layer has a thickness ranging from about 30 angstroms to about 200 angstroms.

21. A method for forming a CMOS device comprising:
forming a first oxide layer over a tensile stress nitride layer, wherein the tensile stress nitride layer is formed over an NMOS device and a PMOS device;
exposing the PMOS device by removing portions of the first oxide layer and the tensile stress nitride layer over the PMOS device;
forming a second oxide layer over the remaining portion of the first oxide layer and over the exposed PMOS device;
forming a compressive stress nitride layer over the second oxide layer; and
removing a portion of the compressive stress nitride layer that is formed over the NMOS device.

22. The method of claim 21, wherein the second oxide layer has a thickness ranging from about 30 angstroms to about 200 angstroms.
